(19) United States
(12) Patent Application Publication
(10) Pub. No.: US 2003/0192478 A1
(43) Pub. Date: Oct. 16, 2003

(54) Plasma CVD apparatus comprising susceptor with ring

(75) Inventors: Naoto Tsuji, Tokyo (JP); Ryo Kawaguchi, Tokyo (JP); Atsuki Fukazawa, Tokyo (JP); Rei Tanaka, Tokyo (JP)

Correspondence Address: KNOBBE MARTENS OLSON & BEAR LLP, 2040 MAIN STREET, FOURTEENTH FLOOR, IRVINE, CA, 92614, US

(73) Assignee: ASM JAPAN K.K., Tokyo (JP)

(21) Appl. No.: 10/412,822

(22) Filed: Apr. 11, 2003

(30) Foreign Application Priority Data
Apr. 16, 2002 (JP) 2002-112837

(51) Int. Cl. C23C 16/00

(52) U.S. Cl. 118/723 E

(57) ABSTRACT

A plasma CVD apparatus includes a vacuum chamber, a showerhead, and a susceptor characterized in that an insulation ring is placed and embedded in a peripheral portion of the susceptor to increase the electrically effective distance between the showerhead and the susceptor, both of which functions as electrodes.

### BACKGROUND OF THE INVENTION

1. Field of the Invention

The present invention relates to a plasma CVD apparatus for forming a thin film on a semiconductor wafer, and it particularly relates to a plasma CVD apparatus characterized by its susceptor structures.

2. Description of the Related Art

In the past, plasma CVD has been used for forming a thin film on a workpiece to be processed such as a semiconductor wafer. FIG. 1 shows a schematic view of a conventional plasma CVD apparatus. The plasma CVD apparatus 1 includes a reaction chamber 6. Inside the reaction chamber 6, a susceptor 3 for placing thereon a semiconductor wafer 4 is disposed. The susceptor 3 is supported by a heater 2. The heater 2 maintains the semiconductor wafer 4 at a given temperature (e.g., 350 to 450° C.). The susceptor 3 serves as one electrode for plasma discharge and is grounded 11 through the reaction chamber 6. Inside the reaction chamber 6, a showerhead 9 is disposed parallel to and opposing to the susceptor 3. The showerhead 9 has a number of fine pores at its bottom, from which a jet of source gas is emitted evenly to the semiconductor wafer 4. At the center of the showerhead 9, a source gas inlet port 5 is provided, and source gas is brought in the showerhead 9 through a gas line (not shown). The gas inlet port 5 is electrically insulated from the reaction chamber 6. The showerhead 9 serves as the other electrode for plasma discharge and is connected to the primary radio-frequency power source 7 and the secondary radio-frequency power source 8 through the source gas inlet port 5. With this setup, a plasma reaction field is generated in the proximity of the semiconductor wafer 4. At the bottom of the reaction chamber 6, an exhaust port 10 connected to an external vacuum pump (not shown) is provided. A type and quality of a film formed on a surface of the semiconductor wafer 4 vary according to a type and a flow rate of source gas, a temperature, a type of RF frequency and a space distribution of plasma.

### SUMMARY OF THE INVENTION

Uniformity of a film formed on a semiconductor wafer is closely related to a plasma density distribution in a reaction area and gas retention time. Generally, in a capacitive coupled type of plasma CVD apparatus, a distribution of electric field intensity generated between electrodes (approximately Ø350 mm) has a characteristic that the intensity is the strongest at the center and gradually dwindles radially toward the outside. In other words, an electric field near the center of the semiconductor wafer is relatively stronger than an electric field radially closed to the outside. In conventional plasma CVD , an intensity distribution in a deposition area is ±7% in the case of a Ø300 mm semiconductor wafer.

In a conventional plasma CVD apparatus shown in FIG. 1, based on the electric field intensity, the plasma density tends to be high at the center of the semiconductor wafer and low in an outer circumferential portion. Consequently, affected by the plasma density distribution, a film is relatively thick at the center of the semiconductor wafer and relatively thin in the outer circumferential portion. Conventionally, such film thickness variations may be corrected by controlling a gas flow rate, a gas mixing ratio, RF frequency, RF power intensity, etc. However, there were disadvantages in the conventional methods, including complicated operation and low process stability, because altering these parameters changes film quality and a deposition speed.

The present invention has been achieved in view of these disadvantages. An object of the present invention is to provide a plasma CVD apparatus which can form a thin film having uniform film thickness and quality.

Another object of the present invention is to provide a plasma CVD apparatus with high process stability, a simple structure and low apparatus cost.

To achieve the above-mentioned objects, the plasma CVD apparatus according to an embodiment of the present invention comprises as follows:

A plasma CVD apparatus comprises a vacuum chamber comprising a showerhead and a susceptor, between which electric voltage is applied to generate a plasma, said susceptor comprising an inner portion and a peripheral portion, said peripheral portion being in the vicinity of a periphery of a substrate to be placed on the susceptor, wherein an electrically effective distance between the showerhead and the susceptor is greater in the periphery portion than in the inner portion.

In the above, in an embodiment, the peripheral portion of the susceptor is a circularly formed recess to increase the electrically effective distance in the peripheral portion. In another embodiment, the peripheral portion of the susceptor is composed of a dielectric material to increase the electrically effective distance in the peripheral portion. In either case, the electrically effective distance between the showerhead and the susceptor is greater in the peripheral portion than in the inner portion, so that uniformity of a film can effectively be achieved without complicated operation control.

As described in the background section, the plasma density tends to be high at the center of the semiconductor wafer and low in an outer circumferential portion. Such a phenomenon can be explained based on the electric field intensity generated between the electrodes. According to the electric field intensity distribution, in order to increase the thickness of a film, the distance between the electrodes may need to be closer. However, to the contrary, in the present invention, by widening the distance between the electrodes in the vicinity of the periphery of the substrate, it is possible to effectively increase the thickness of a film near the periphery of a substrate, thereby forming a film having uniform thickness. This phenomenon may be explained based on (a) a residence time of a reaction gas and (b) a plasma density. That is, the wider the distance between the electrodes, the slower the flow rate of the reaction gas becomes, thereby increasing the deposition rate of a film. Further, the wider the distance between the electrodes, the higher the plasma density becomes, thereby increasing the deposition rate of a film.

The above theories may apply only when the difference in distance between the electrodes is less than a few centimeters, especially less than 5 mm, for example (in some cases, the theories are possibly applicable up to a distance of approximately five centimeters). Interestingly, even if the distance between the electrodes is maintained by using an insulation ring instead of forming a recess or step so as to maintain the residence time of a reaction gas while increasing the electrically effective distance between the electrodes, it is still possible to increase the thickness of a film. In that case, the plasma density theory may explain the deposition phenomenon. There is a related theory which is known as Paschen's law. According to Paschen's law, there is a certain distance between electrodes where discharge initiation voltage is minimum. In a first range where the distance is shorter than the above-defined distance, the longer the distance, the lower the discharge initiation voltage becomes. In a second range where the distance is greater than the above-defined distance, the longer the distance, the higher the discharge initiation voltage becomes. Although the present invention is not limited to the above theories, the present invention may be explained as follows: The distance between the electrodes in the vicinity of the periphery of a substrate is in the first range so that the greater the distance, the lower the discharge initiation voltage becomes, thereby increasing a plasma density and increasing the thickness of the film.

The present invention also relates to a susceptor itself. In addition to the distinct configurations of a plasma CVD apparatus explained above, the susceptor itself is distinct.

For purposes of summarizing the invention and the advantages achieved over the prior art, certain objects and advantages of the invention have been described above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

Further aspects, features and advantages of this invention will become apparent from the detailed description of the preferred embodiments which follow.

### BRIEF DESCRIPTION OF THE DRAWINGS

These and other features of this invention will now be described with reference to the drawings of preferred embodiments which are intended to illustrate and not to limit the invention.

FIG. 1 is a schematic view of a conventional plasma CVD apparatus.

FIG. 2 is a schematic view of a preferred embodiment of the CVD apparatus according to the present invention.

FIG. 3 is a modified example of a susceptor used in the CVD apparatus according to the present invention.

FIG. 4 is a graph showing the insulation ring thickness dependency of a thickness of an insulation film deposited at the edge of a semiconductor wafer by the plasma CVD apparatus shown in FIG. 2, which uses an insulation ring made of aluminum oxide.

FIG. 5 is a graph showing the insulation ring thickness dependency of a thickness of an insulation film deposited at the edge of a semiconductor wafer by the plasma CVD apparatus shown in FIG. 2, which uses an insulation ring made of aluminum nitride.

FIG. 6 is a graph showing the insulation ring thickness dependency of a thickness of an insulation film deposited at the edge of a semiconductor wafer by the plasma CVD apparatus shown in FIG. 2, which uses an insulation ring made of magnesium oxide.

FIG. 7 is a graph showing the insulation ring internal diameter dependency of a thickness of an insulation film deposited at the edge of a semiconductor wafer by the plasma CVD apparatus shown in FIG. 2.

FIG. 8 is a graph showing the insulation ring thickness dependency of a thickness distribution of an insulation film deposited by the plasma CVD apparatus shown in FIG. 2.

FIG. 9 is a graph showing the insulation ring thickness dependency of a thickness of an insulation film deposited at the edge of a semiconductor wafer by the plasma CVD apparatus, which uses the susceptor shown in FIG. 3.

FIG. 10 is a graph showing the insulation ring internal diameter dependency of a thickness of an insulation film deposited at the edge of a semiconductor wafer by the plasma CVD apparatus, which uses the susceptor shown in FIG. 3.

Explanation of symbols used is as follows: 2: Heater; 4: Semiconductor wafer; 5: Source gas inlet port; 6: Reaction chamber; 7: Primary radio-frequency power source; 8: Secondary radio-frequency power source; 9: Showerhead; 10: Exhaust port; 11: Grounding; 20: Plasma CVD apparatus; 21: Susceptor; 22: Insulation ring.

### DETAILED DESCRIPTION OF THE PREFERRED EMBODIMENTS

As explained above, in an embodiment, a plasma CVD apparatus comprises a vacuum chamber comprising a showerhead and a susceptor, between which electric voltage is applied to generate a plasma, said susceptor comprising an inner portion and a peripheral portion, said peripheral portion being in the vicinity of a periphery of a substrate to be placed on the susceptor, wherein an electrically effective distance between the showerhead and the susceptor is greater in the periphery portion than in the inner portion. In the above, the peripheral portion of the susceptor may be a circularly formed recess to increase the electrically effective distance in the peripheral portion, or may be composed of a dielectric material to increase the electrically effective distance in the peripheral portion.

When using a low dielectric constant material, the material of the peripheral portion may have a dielectric constant (∈) of about 10 or lower, including 9, 8, 7, 6, 5, 4, 3, 2, and a range including any two of the foregoing. If a circular recess is used, the dielectric constant is about one as explained below. Any suitable material can be used for the peripheral portion and may be selected from the group consisting of metal oxides and metal nitrides. Preferably, the material of the peripheral portion may be an aluminum oxide or nitride, or a magnesium oxide or nitride, such as alumina (Al₂O₃, ∈=about 8), aluminum nitride (AlN, ∈=about 8.6-8.7), or magnesium oxide (MgO, ∈=about 6 to about 8). The dielectric constant varies especially in the case of sintered bodies such as AlN or MgO. The material of the inner portion of the susceptor may be aluminum, for example.

Because the dielectric constant of a gas at one atm is nearly one, the dielectric constant of a gas existing in a moderate vacuum is also considered to be nearly one. In a capacitive coupled type of plasma CVD apparatus using a showerhead and a susceptor facing each other as electrodes, the use of a material whose dielectric constant is ∈ on the susceptor is equivalent to inserting a dielectric material with a dielectric constant of ∈ in a capacitor, and an electrically effective distance between the electrodes (an effective electrode distance) can be calculated. In this case, an effective electrode distance shortens by (∈−1)/∈ of the thickness of a plate made of the material, rather than the physical thickness of the plate. If the surface level of the susceptor is reduced by the thickness of the plate and the plate is placed in the recessed portion, an effective electrode distance lengthens by 1/∈ of the thickness of the plate because the effective thickness of the plate which functions as a part of the electrode is (∈−1)/∈ of the physical thickness.

A reduction of the effective electrode distance may be in the range of about 0.1 mm to about 10 mm, including 0.5 mm, 1 mm, 1.5 mm, 2 mm, 3 mm, 4 mm, 6 mm, 8 mm, and a range including any two of the foregoing. In this connection, the distance between the showerhead and the susceptor may be in the range of about 5 mm to about 50 mm, including 10 mm, 15 mm, 20 mm, 30 mm, 40 mm, and a range including any two of the foregoing. A reduction of the effective electrode distance may also vary depending on the distance between the showerhead and the susceptor. In an embodiment, the reduction may be about 1% to about 20% (including 5%, 10%, 15%, and a range including any two of the foregoing) of the distance between the showerhead and the susceptor.

The peripheral portion of the susceptor may preferably be a ring which is fitted in a recess formed outside the inner portion. The ring may be fitted in the recess without a difference in level. In an embodiment, the ring has a thickness of about 0.5 mm to about 30 mm, including 1.0 mm, 2.0 mm, 3.0 mm, 4.0 mm, 5.0 mm, 1 mm, 5 mm, 10 mm, 20 mm, and a range including any two of the foregoing. The thickness depends on the dielectric constant of the material as explained above.

Further, in an embodiment, the peripheral portion may have an inner diameter ranging from about 80% to about 120% (including 85%, 90%, 95%, 100%, 115%, and a range including any two of the foregoing) of the diameter of the substrate.

In an embodiment, the peripheral portion may have an outer diameter ranging from about 100% to about 150% (including 105%, 110%, 120%, 130%, 140%, and a range including any two of the foregoing) of the diameter of the substrate. The outer diameter of the peripheral portion may mean the periphery of the susceptor, although it is not necessary.

In a modified configuration, the inner portion of the susceptor may be concave, and the distance between the susceptor and the showerhead may be the longest at the center of the inner portion. This configuration is useful to avoid particle contamination on the back side of the substrate in contact with the susceptor surface.

In a preferable embodiment, a plasma CVD apparatus comprises a vacuum chamber, a showerhead which is disposed inside said vacuum chamber, and a susceptor for placing thereon a workpiece to be processed, said susceptor being disposed parallel to and opposing to said showerhead and being characterizable in that an insulation ring is embedded in a peripheral portion of said susceptor. Accordingly, the present invention will be described in detail by referring to figures. The present invention is not limited to embodiments described blow.

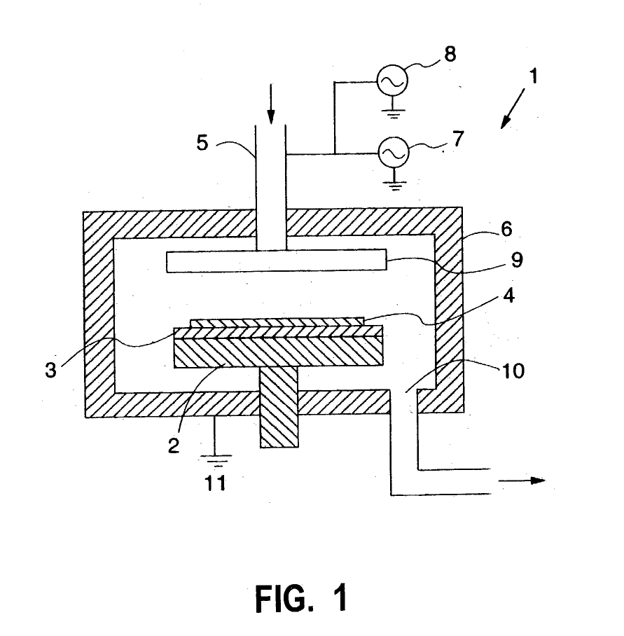

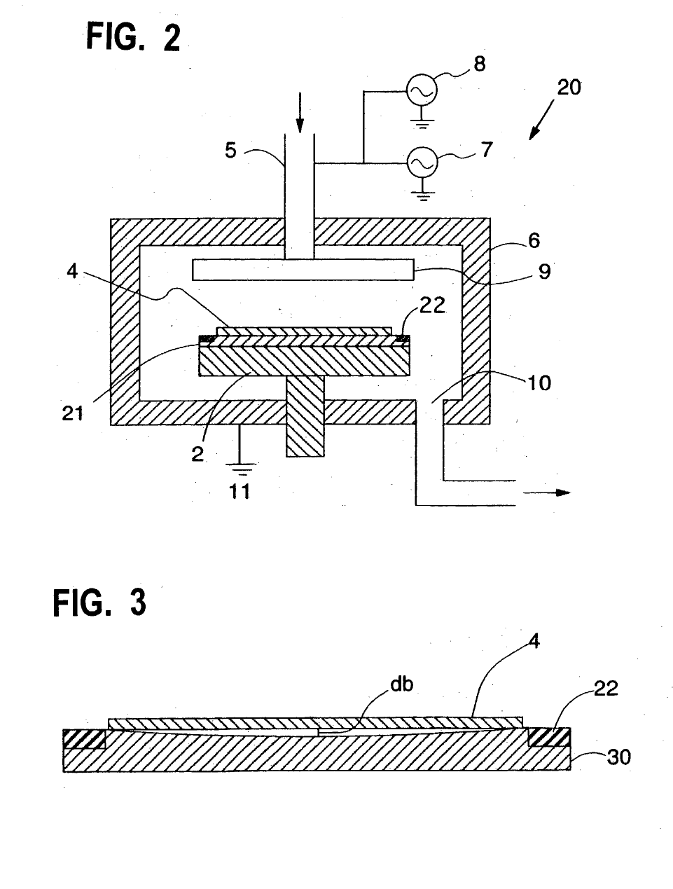

FIG. 2 shows a schematic view of a preferred embodiment of the plasma CVD apparatus according to the present invention. The same symbols are used for parts which are the same as the parts shown in FIG. 1. In the present invention, source gas brought in from the showerhead 9 comprises silicon hydrocarbon containing multiple alkoxy groups, and Ar or He can be contained as an added gas. A frequency of the primary radio-frequency power source 7 is preferably 27.12 MHz, but it can be other than this if it is 2 MHz or higher. A frequency of the secondary radio-frequency power source 8 is preferably 400 kHz, but it can be other than this if it is 2 MHz or lower.

A distinguishing characteristic of the plasma CVD apparatus 20 according to the present invention is that an insulation ring 22 is laid being embedded in a surface peripheral portion of a susceptor 21. The insulation ring 22 comprises preferably alumina (Al₂O₃). Aluminum nitride (AlN) or magnesium oxide (MgO) can be also used. An inner diameter of the insulation ring 22 is preferably in the range of about 80% to about 120% of a diameter of the semiconductor wafer 4. An outer diameter of the insulation ring 22 is preferably in the range of about 100% to about 150% of the diameter of the semiconductor wafer 4. The thickness of the insulation ring 22 is preferably in the range of about 0.5 mm to about 30 mm.

A function of the insulation ring is described below. For a capacitive coupled type of plasma CVD apparatus, a pressure and an electrode distance are important factors in terms of generating and maintaining plasma, and this type of plasma CVD apparatus is also a called capacitive-coupling-type plasma CVD apparatus. Under standard conditions for forming a low-dielectric-constant insulation film, which were examined in experiments described below, by increasing the electrode distance slightly, plasma can be generated efficiently and a film thickness around the proximity can be controlled to be thick.

Two parallel-flat-plate electrodes opposing to each other, i.e. the susceptor 21 and the showerhead 9, which are shown in FIG. 2, correspond to counter electrodes of a capacitor. The dielectric constant of vacuum is one by definition. Because the dielectric constant of a gas at one atm is nearly one, the dielectric constant of a gas existing in a moderate vacuum is also considered to be nearly one. Because placing an alumina plate whose dielectric constant is 8 on the susceptor is equivalent to inserting a dielectric material with a dielectric constant of 8 in a capacitor, an effective distance between the electrodes (an effective electrode distance) can be calculated. In this case, an effective electrode distance shortens by ⅞ of the thickness of the alumina plate instead of the physical thickness of the plate. If the surface level of the susceptor is reduced by the thickness of the alumina plate and the alumina plate is placed in the recessed portion, an effective electrode distance lengthens by 1/8 of the thickness of the alumina plate because the effective thickness of the plate which functions as a part of the electrode is 7/8 of the physical thickness.

As described, by using the insulation ring, an effective electrode distance in outer circumferential portion of a semiconductor wafer can be increased accurately. By this feature, a film thickness at the peripheral portion of a semiconductor wafer can be controlled at a desired thickness; the uniformity of the film thickness can be improved.

Another embodiment of the plasma CVD apparatus according to the present invention is described. FIG. 3 shows another embodiment of the susceptor according to the present invention. A surface of a susceptor 30 is formed as a rotating surface which is concave. The concavity of the susceptor surface is constructed so that a distance from a showerhead is the longest at the center and gradually shortens in a radius direction. A depth of the concavity at the center of the susceptor 30 is preferably in the range of 0.1 to 4 mm. As shown in FIG. 3, a semiconductor wafer 4 contacts the susceptor 30 only in an outer circumferential portion, enabling to prevent damage to the back side of the semiconductor wafer 4 and particle contamination.

### EXAMPLES

Experiments conducted for evaluating uniformity of a thickness of a low-k insulation film formed using the plasma CVD apparatus are described below.

### Experiment 1

Using the plasma CVD apparatus 20 shown in FIG. 2, an experiment for forming an insulation film on a Ø300 mm silicon wafer was conducted.

Experimental Conditions:

Main source gas: DM-DMOS (dimethy-dimethoxysilane) 200 sccm

Added gas: He 400 sccm

Primary radio-frequency power source: 27.12 MHz at 2.5 W/cm²

Secondary radio-frequency power source: 400 kHz at 0.1 W/cm²

Deposition pressure: 500 Pa

Material of the insulation ring: Aluminum oxide

Inner diameter of the insulation ring: 304 mm

Outer diameter of the insulation ring: 360 mm

Thickness of the insulation ring: 1 mm to 20 mm

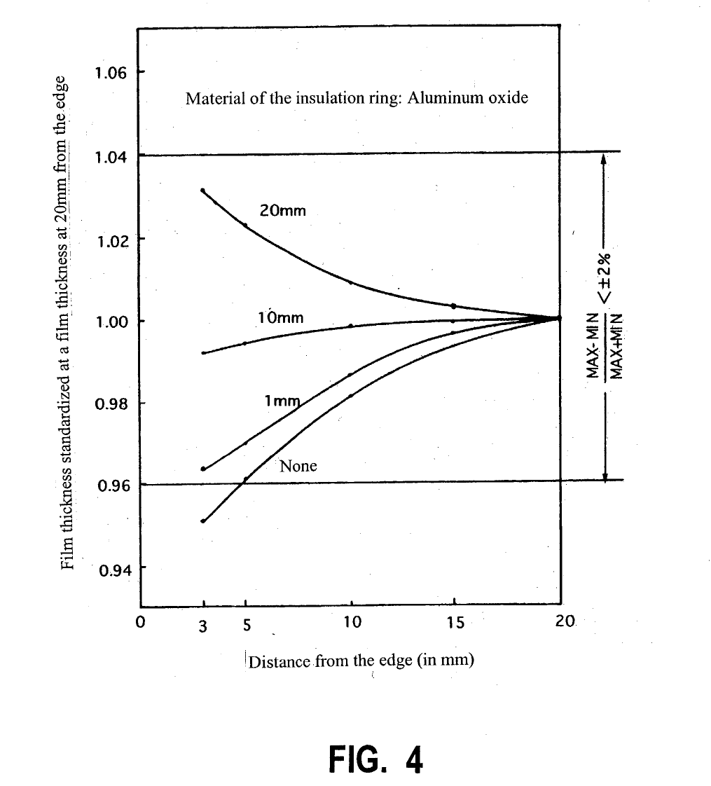

FIG. 4 is a graph showing the relation between the distance from the edge of a semiconductor wafer and the film thickness standardized at 20 mm from the edge of the semiconductor wafer when the insulation film was formed on the semiconductor wafer under the above-mentioned experimental conditions. From the graph, it is seen that under the above-mentioned experimental conditions, with the thickness of the insulation ring in the range of 1 mm to 20 mm, the film thickness in the proximity of the edge of the semiconductor wafer was able to be controlled within ±2%. From this, it is seen that a film thickness distribution in the entire semiconductor wafer can be uniformized within ±3%.

### Experiment 2

Using the plasma CVD apparatus 20 shown in FIG. 2, an experiment for forming an insulation film on a Ø300 mm silicon wafer was conducted.

Experimental Conditions:

Main source gas: DM-DMOS (dimethy-dimethoxysilane) 200 sccm

Added gas: He 400 sccm

Primary radio-frequency power source: 27.12 MHz at 2.5 W/cm²

Secondary radio-frequency power source: 400 kHz at 0.1 W/cm²

Deposition pressure: 500 Pa

Material of the insulation ring: Aluminum nitride

Inner diameter of the insulation ring: 304 mm

Outer diameter of the insulation ring: 360 mm

Thickness of the insulation ring. 1 mm to 20 mm

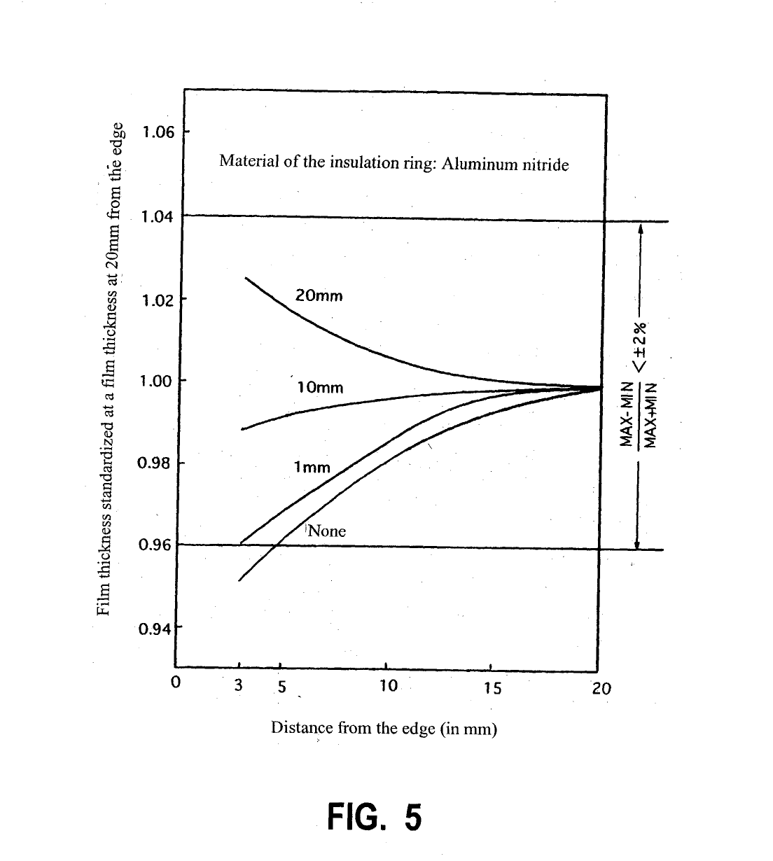

FIG. 5 is a graph showing the relation between the distance from the edge of a semiconductor wafer and the film thickness standardized at 20 mm from the edge of the semiconductor wafer when an insulation film was formed on the semiconductor wafer under the above-mentioned experimental conditions. From the graph, it is seen that under the above-mentioned experimental conditions, with the thickness of the insulation ring in the range of 1 mm to 20 mm, the film thickness in the proximity of the edge of the semiconductor wafer was able to be controlled within ±2%. From this, it is seen that a film thickness distribution in the entire semiconductor wafer can be uniformized within ±3%.

### Experiment 3

Using the plasma CVD apparatus 20 shown in FIG. 2, an experiment for forming an insulation film on a Ø300 mm silicon wafer was conducted.

Experimental Conditions:

Main source gas: DM-DMOS (dimethy-dimethoxysilane) 200 sccm

Added gas: He 400 sccm

Primary radio-frequency power source: 27.12 MHz at 2.5 W/cm²

Secondary radio-frequency power source: 400 kHz at 0.1 W/cm²

Deposition pressure: 500 Pa

Material of the insulation ring: Magnesium oxide

Inner diameter of the insulation ring: 304 mm

Outer diameter of the insulation ring: 360 mm

Thickness of the insulation ring: 1 mm to 20 mm

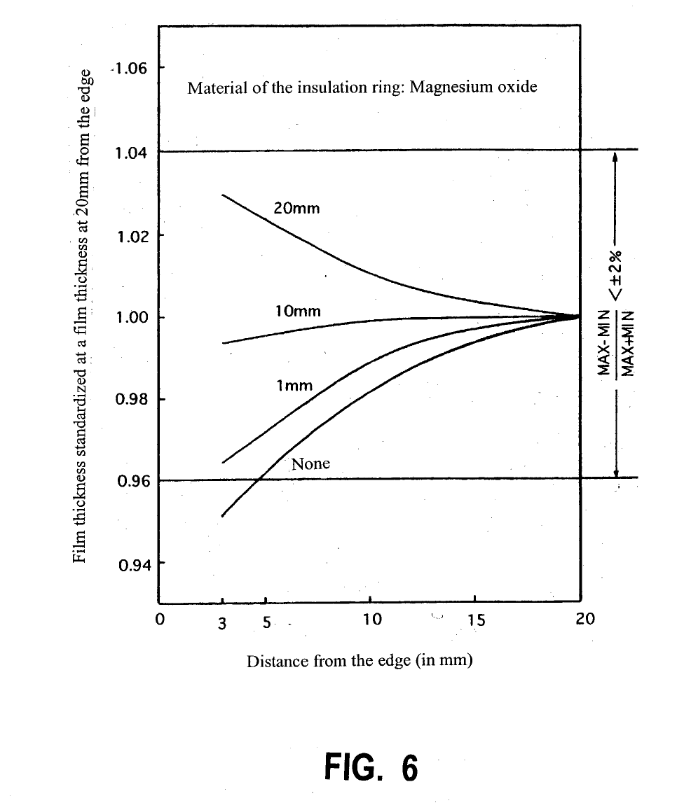

FIG. 6 is a graph showing the relation between the distance from the edge of a semiconductor wafer and the film thickness standardized at 20 mm from the edge of the semiconductor wafer when an insulation film was formed on the semiconductor wafer under the above-mentioned experimental conditions. From the graph, it is seen that under the above-mentioned experimental conditions, with the thickness of the insulation ring in the range of 1 mm to 20 mm, the film thickness in the proximity of the edge of the semiconductor wafer was able to be controlled within ±2%. From this, it is seen that a film thickness distribution in the entire semiconductor wafer can be uniformized within ±3%.

### Experiment 4

Using the plasma CVD apparatus 20 shown in FIG. 2, an experiment for forming an insulation film on a Ø300 mm silicon wafer was conducted.

Experimental Conditions:

Main source gas: DM-DMOS (dimethy-dimethoxysilane) 200 sccm

Added gas: He 400 sccm

Primary radio-frequency power source: 27.12 MHz at 2.5 W/cm²

Secondary radio-frequency power source: 400 kHz at 0.1 W/cm²

Deposition pressure: 500 Pa

Material of the insulation ring: Aluminum oxide

Inner diameter of the insulation ring: 301 mm to 315 mm

Outer diameter of the insulation ring: 390 mm

Thickness of the insulation ring: 10 mm

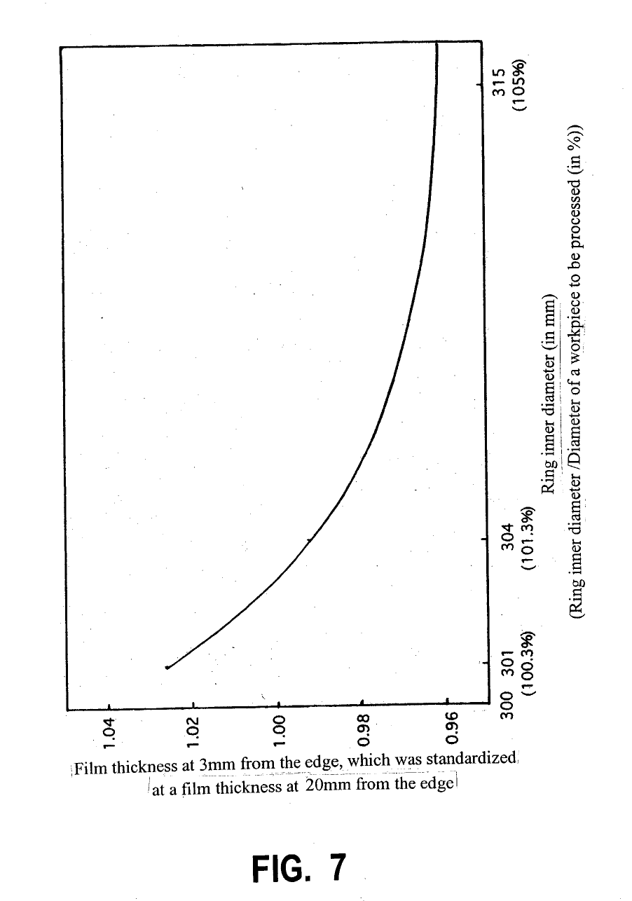

FIG. 7 is a graph showing the relation between the inner diameter of the insulation ring and the film thickness at 3 mm from an edge which is standardized at 20 mm from the edge of the semiconductor wafer when an insulation film was formed on the semiconductor wafer under the above-mentioned experimental conditions. From the graph, it is seen that under the above-mentioned experimental conditions, with the inner diameter of the insulation ring in the range of 301 mm to 315 mm (i.e. in the range of 100.3% to 105% to a diameter of the semiconductor wafer), the film thickness in the proximity of the edge of the semiconductor wafer was able to be controlled within ±2%. From this, it is seen that a film thickness distribution in the entire semiconductor wafer can be uniformized within ±3%.

### Experiment 5

Using the plasma CVD apparatus 20 shown in FIG. 2, an experiment for forming an insulation film on a Ø300 mm silicon wafer was conducted.

Experimental Conditions:

Main source gas: DM-DMOS (dimethy-dimethoxysilane) 200 sccm

Sub source gas: O₂ 100 sccm N₂ 200 sccm

Added gas: He 400 sccm

Primary radio-frequency power source: 27.12 MHz at 1.8 W/cm²

Secondary radio-frequency power source: 400 kHz at 0.1 W/cm²

Deposition pressure: 300 Pa

Material of the insulation ring: Aluminum oxide

Inner diameter of the insulation ring: 270 mm

Outer diameter of the insulation ring: 330 mm

Thickness of the insulation ring: 1 mm to 20 mm

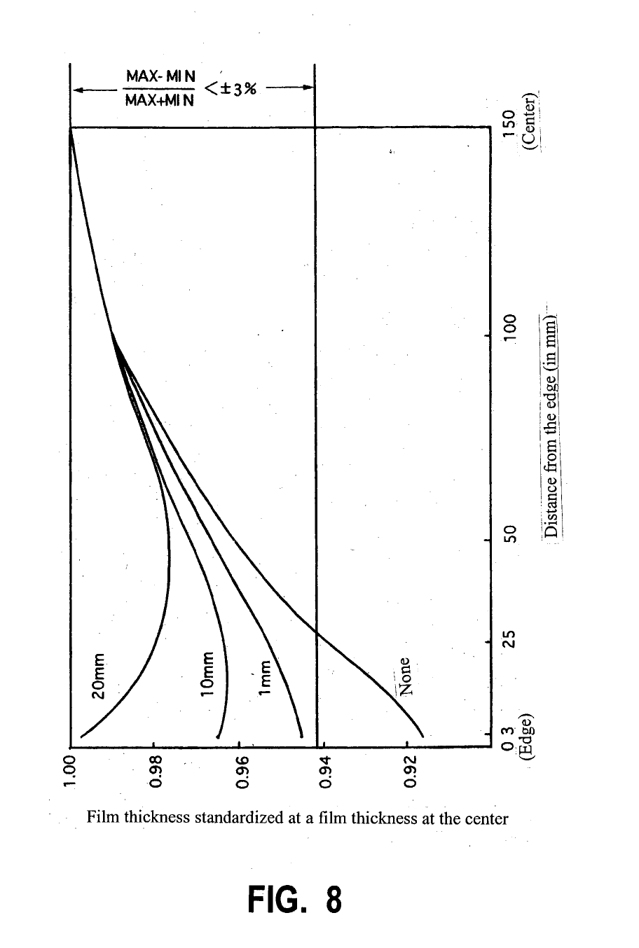

FIG. 8 is a graph showing the relation between the distance from the edge of a semiconductor wafer and the film thickness standardized at a film thickness at the center of the semiconductor wafer when an insulation film was formed on the semiconductor wafer under the above-mentioned experimental conditions. From the graph, it is seen that under the above-mentioned experimental conditions, with the thickness of the insulation ring in the range of 1 mm to 20 mm, a film thickness distribution in the entire semiconductor wafer can be controlled within ±3%. What is noted here is that: Under the above-mentioned deposition conditions, it is necessary to increase the film thickness in the proximity of the edge of the semiconductor wafer as the film thickness at the center of the semiconductor wafer thickens, but by setting the inner diameter of the insulation ring at 90% (270 mm) of the diameter of the semiconductor wafer, a preferred film thickness distribution can be obtained.

### Experiment 6

Using the plasma CVD apparatus according to the present invention, which uses the susceptor 30 shown in FIG. 3, an experiment for forming an insulation film on a Ø300 mm silicon wafer was conducted.

Experimental Conditions:

Main source gas: DM-DMOS 200 sccm

Added gas: He 400 sccm

Primary radio-frequency power source: 27.12 MHz at 2.5 W/cm²

Secondary radio-frequency power source: 400 kHz at 0.1 W/cm²

Deposition pressure: 500 Pa

Material of the insulation ring: Aluminum oxide

Inner diameter of the insulation ring: 304 mm

Outer diameter of the insulation ring: 360 mm

Thickness of the insulation ring: 1 to 20 mm

Depth of the concavity of the susceptor: db=1 mm

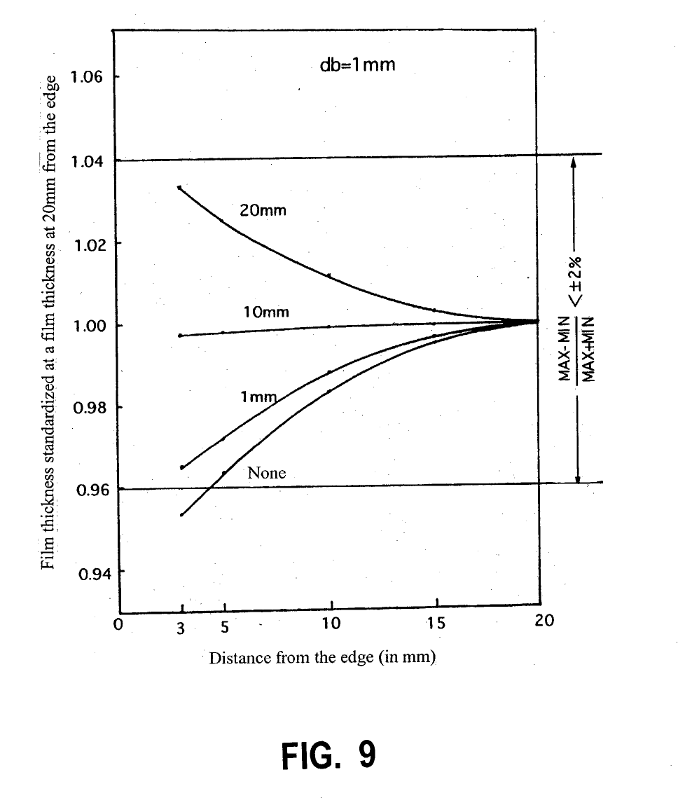

FIG. 9 is a graph showing the relation between the distance from the edge of a semiconductor wafer and the film thickness standardized at a film thickness at 20 mm from the edge of the semiconductor wafer when an insulation film was formed on the semiconductor wafer under the above-mentioned experimental conditions. From the graph, it is seen that under the above-mentioned experimental conditions, with the thickness of the insulation ring in the range of 1 mm to 20 mm, the film thickness in the proximity of the edge of the semiconductor wafer was able to be controlled within ±2%. From this, it is seen that a film thickness distribution in the entire semiconductor wafer can be uniformized within ±3%.

### Experiment 7

Using the plasma CVD apparatus according to the present invention, which uses the susceptor 30 shown in FIG. 3, an experiment for forming an insulation film on a Ø300 mm silicon wafer was conducted.

Experimental Conditions:

Main source gas: DM-DMOS 200 sccm

Added gas: He 400 sccm

Primary radio-frequency power source: 27.12 MHz at 2.5 W/cm²

Secondary radio-frequency power source: 400 kHz at 0.1 W/cm²

Deposition pressure: 500 Pa

Material of the insulation ring: Aluminum oxide

Inner diameter of the insulation ring: 301 mm to 315 mm

Outer diameter of the insulation ring: 390 mm

Thickness of the insulation ring: 10 mm

Depth of the concavity of the susceptor: db=1 mm

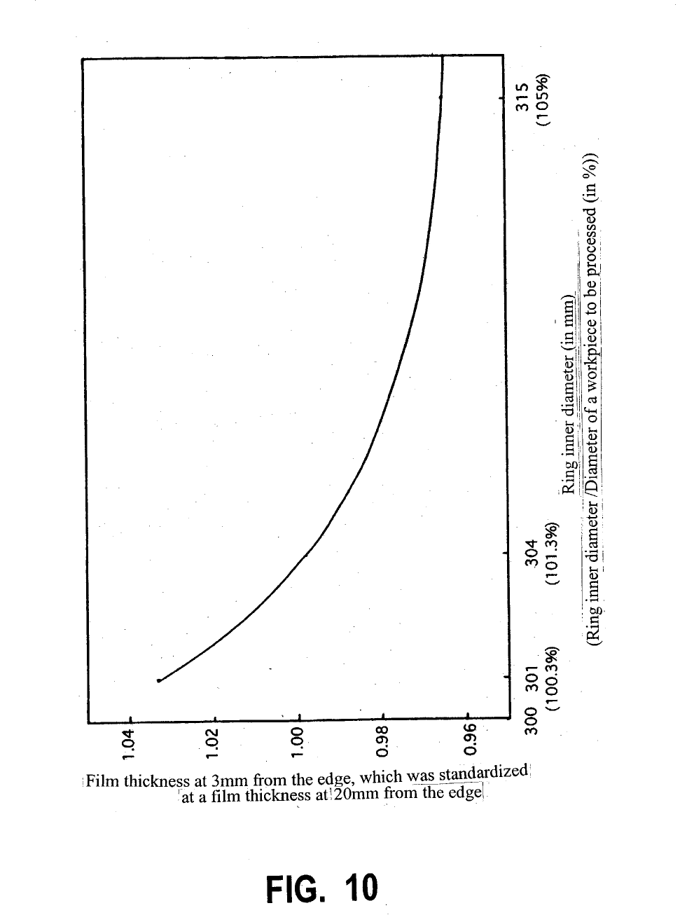

FIG. 10 is a graph showing the relation between the inner diameter of the insulation ring and the film thickness at 3 mm from an edge, which is standardized at a film thickness at 20 mm from the edge of the semiconductor wafer, when an insulation film was formed on the semiconductor wafer under the above-mentioned experimental conditions. From the graph, it is seen that under the above-mentioned experimental conditions, with the inner diameter of the insulation ring in the range of 301 mm to 315 mm (i.e. in the range of 100.3% to 105% to a diameter of the semiconductor wafer), the film thickness in the proximity of the edge of the semiconductor wafer was able to be controlled within ±2%. From this, it is seen that a film thickness distribution in the entire semiconductor wafer can be uniformized within ±3%.

Effects

Using an embodiment of the plasma CVD apparatus according to the present invention, an insulation film with improved uniformity of film thickness and film quality can be formed.

Using an embodiment of the plasma CVD apparatus according to the present invention, process stability can be improved and costs can be reduced.

It will be understood by those of skill in the art that numerous and various modifications can be made without departing from the spirit of the present invention. Therefore, it should be clearly understood that the forms of the present invention are illustrative only and are not intended to limit the scope of the present invention.

What is claimed is:

1. A plasma CVD apparatus comprising a vacuum chamber comprising a showerhead and a susceptor, between which electric voltage is applied to generate a plasma, said susceptor comprising an inner portion and a peripheral portion, said peripheral portion being in the vicinity of a periphery of a substrate to be placed on the susceptor, wherein an electrically effective distance between the showerhead and the susceptor is greater in the periphery portion than in the inner portion.

2. The apparatus as claimed in claim 1, wherein the peripheral portion of the susceptor is a circularly formed recess to increase the electrically effective distance in the peripheral portion.

3. The apparatus claimed in claim 1, wherein the peripheral portion of the susceptor is composed of a dielectric material to increase the electrically effective distance in the peripheral portion.

4. The apparatus claimed in claim 3, wherein the material of the peripheral portion has a dielectric constant of about 10 or lower.

5. The apparatus claimed in claim 4, wherein the material of the peripheral portion is selected from the group consisting of metal oxides and metal nitrides.

6. The apparatus claimed in claim 5, wherein the material of the peripheral portion is an aluminum oxide or nitride, or a magnesium oxide or nitride.

7. The apparatus claimed in claim 3, wherein the peripheral portion of the susceptor is a ring which is fitted in a recess formed outside the inner portion.

8. The apparatus claimed in claim 7, wherein the ring is fitted in the recess without a difference in level.

9. The apparatus claimed in claim 7, wherein the ring has a thickness of about 0.5 mm to about 30 mm.

10. The apparatus claimed in claim 1, wherein the peripheral portion has an inner diameter ranging from about 80% to about 120% of the diameter of the substrate.

11. The apparatus as claimed in claim 1, wherein the peripheral portion has an outer diameter ranging from about 100% to about 150% of the diameter of the substrate.

12. The apparatus as claimed in claim 1, wherein the inner portion of the susceptor is concave, and the distance between the susceptor and the showerhead is the longest at the center of the inner portion.

13. A susceptor adapted to be installed in a vacuum chamber of a plasma CVD apparatus, comprising an inner portion and a peripheral portion, said peripheral portion being in the vicinity of a periphery of a substrate to be placed on the susceptor, said peripheral portion being configured to have a greater electrically effective distance from a showerhead provided in the vacuum chamber than that of the inner portion.

14. The susceptor as claimed in claim 13, wherein the peripheral portion of the susceptor is a circularly formed recess to increase the electrically effective distance in the peripheral portion.

15. The susceptor claimed in claim 13, wherein the peripheral portion of the susceptor is composed of a dielectric material to increase the electrically effective distance in the peripheral portion.

16. The susceptor claimed in claim 15, wherein the material of the peripheral portion has a dielectric constant of about 10 or lower.

17. The susceptor claimed in claim 16, wherein the material of the peripheral portion is selected from the group consisting of metal oxides and metal nitrides.

18. The susceptor claimed in claim 17, wherein the material of the peripheral portion is an aluminum oxide or nitride, or a magnesium oxide or nitride.

19. The susceptor claimed in claim 15, wherein the peripheral portion of the susceptor is a ring which is fitted in a recess formed outside the inner portion.

20. The susceptor claimed in claim 19, wherein the ring is fitted in the recess without a difference in level.

21. The susceptor claimed in claim 19, wherein the ring has a thickness of about 0.5 mm to about 30 mm.

22. The susceptor claimed in claim 13, wherein the peripheral portion has an inner diameter ranging from about 80% to about 120% of the diameter of the substrate.

23. The susceptor as claimed in claim 13, wherein the peripheral portion has an outer diameter ranging from about 100% to about 150% of the diameter of the substrate.

24. The susceptor as claimed in claim 13, wherein the inner portion of the susceptor is concave, and the distance between the susceptor and the showerhead is the longest at the center of the inner portion.

25. A plasma CVD apparatus comprising a vacuum chamber, a showerhead which is disposed inside said vacuum chamber, and a susceptor for placing thereon a workpiece to be processed, said susceptor being disposed parallel to and opposing to said showerhead and being characterizable in that an insulation ring is embedded in a peripheral portion of said susceptor.

26. The apparatus as claimed in claim 25, wherein said insulation ring has an inner diameter in the range of about 80% to about 120% of the diameter of said workpiece to be processed.

27. The apparatus as claimed in claim 25, wherein said insulation ring has an outer diameter in the range of about 100% to about 150% of a diameter of said workpiece to be processed.

28. The apparatus as claimed in claim 25, wherein said insulation ring has a thickness in the range of about 0.5 mm to about 30 mm.

29. The apparatus as claimed in claim 25, wherein said insulation ring comprises an aluminum oxide or nitride, or a magnesium oxide or nitride.

30. The apparatus as claimed in claim 25, wherein said susceptor has a surface formed as a rotating surface which is concave, and a distance between said susceptor and said showerhead is the longest at the center of the surface of said susceptor and shortens in a radius direction.
